(19) United States
(12) Patent Application Publication
(10) Pub. No.: US 2023/0185992 A1
(43) Pub. Date: Jun. 15, 2023

(54) MANAGING STATES OF A SIMULATED ENVIRONMENT

(71) Applicant: GM Cruise Holdings LLC, San Francisco, CA (US)

(72) Inventors: Benjamin Dunkin, San Francisco, CA (US); Thomas Busser, San Francisco, CA (US); Casey Weaver, San Francisco, CA (US); Caleb Johnson, Oakland, CA (US)

(21) Appl. No.: 17/550,204

(22) Filed: Dec. 14, 2021

(51) Int. Cl. G06F 30/23; G06T 19/00; G05B 13/04

(52) U.S. Cl. CPC G06F 30/23; G05B 13/048; G06T 19/003

(57) ABSTRACT

The disclosed technology provides solutions for managing states of a simulated environment. In some aspects, a processor may be configured to provide a simulation environment for an autonomous vehicle (AV), wherein the simulation environment is associated with a plurality of simulation parameters each having a corresponding value dependent upon a state of the simulation environment. In some cases, the processor may determine at least one function for assessing a value of each of the plurality of simulation parameters at any time within a simulation time period. In some examples, the processor may receive a first query for a first value of at least one simulation parameter from the plurality of simulation parameters at a first time within the simulation time period. In some cases, the processor may return the first value of the at least one simulation parameter at the first time based on the at least one function.

### BACKGROUND

### 1. Technical Field

The disclosed technology provides solutions for improving simulation environments and in particular, the disclosed technology improves the accuracy of simulation parameters throughout timeline state changes within simulation environments.

### 2. Introduction

Autonomous vehicles (AVs) are vehicles having computers and control systems that perform driving and navigation tasks that are conventionally performed by a human driver. As AV technologies continue to advance, they will be increasingly used to improve transportation efficiency and safety. As such, AVs will need to perform many of the functions that are conventionally performed by human drivers, such as performing navigation and routing tasks necessary to provide a safe and efficient transportation. Such tasks may be improved by providing simulated environments that can be used to test the AV software.

### BRIEF DESCRIPTION OF THE DRAWINGS

Certain features of the subject technology are set forth in the appended claims. However, the accompanying drawings, which are included to provide further understanding, illustrate disclosed aspects and together with the description serve to explain the principles of the subject technology. In the drawings:

FIG. 1 illustrates an example of a system for managing one or more Autonomous Vehicles (AVs), in accordance with some aspects of the present technology.

FIG. 2 illustrates an example system for simulating the operation of an autonomous vehicle, in accordance with some aspects of the present technology.

FIG. 3A, FIG. 3B, and FIG. 3C illustrate example states within a simulation environment, in accordance with some aspects of the present technology.

FIG. 4 illustrates a block diagram of an example process for managing state information in a simulation environment, in accordance with some aspects of the present technology.

FIG. 5 illustrates an example processor-based system with which some aspects of the subject technology can be implemented.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a more thorough understanding of the subject technology. However, it will be clear and apparent that the subject technology is not limited to the specific details set forth herein and may be practiced without these details. In some instances, structures and components are shown in block diagram form in order to avoid obscuring the concepts of the subject technology.

One way to improve various aspects of autonomous vehicle (AV) performance, such as navigation and routing functions, is to simulate AV operations for various driving scenarios. The simulation of such scenarios can be performed in a virtual environment, such as a three-dimensional (3D) virtual environment that can be used to generate synthetic AV sensor data that replicates real-world environments.

In some cases, simulation environments can capture and store simulation data based on a clock that provides a time signal (e.g., a tick) to the objects in the simulation. For example, a simulation environment that operates using 100 millisecond (ms) ticks would store data every 100 ms. In some cases, simulation data is only stored for the most recent tick. In other cases, data is stored for a number of prior ticks.

In some examples, tick-based simulation environments may be deficient because the simulation data is not captured between ticks. For instance, a query of a simulation parameter at the 150 ms time in a 100 ms tick-based environment would either fail or would return the value captured at one of the bordering tick marks (e.g., the 100 ms value or the 200 ms value). The values captured at the bordering tick marks are often inaccurate because simulation parameters may change quickly between ticks. In some cases, different aspects of simulation environments may operate using different clocks, which can further complicate implementation of the simulation environment and also further limit the frequency at which simulation data is captured.

The disclosed technology addresses a need in the art for providing a simulation environment that manages the state of the simulated environment. Aspects of the disclosed technology address the foregoing need by providing solutions for accurately determining timeline state changes (e.g., state changes or value changes over time of simulation parameters) in a simulated environment. In some approaches, the disclosed technology provides a novel process for determining one or more functions that can be used to assess the state or value of simulation parameters throughout the entire simulation time period. In some aspects, the present technology can reduce the time and computational resources for performing simulations while improving the accuracy of simulation results.

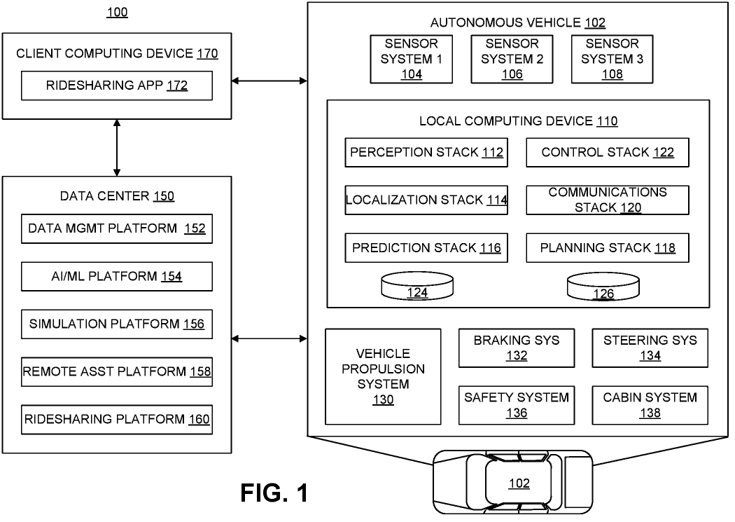

FIG. 1 illustrates an example of an AV management system 100. One of ordinary skill in the art will understand that, for the AV management system 100 and any system discussed in the present disclosure, there can be additional or fewer components in similar or alternative configurations. The illustrations and examples provided in the present disclosure are for conciseness and clarity. Other embodiments may include different numbers and/or types of elements, but one of ordinary skill the art will appreciate that such variations do not depart from the scope of the present disclosure.

In this example, the AV management system 100 includes an AV 102, a data center 150, and a client computing device 170. The AV 102, the data center 150, and the client computing device 170 can communicate with one another over one or more networks (not shown), such as a public network (e.g., the Internet, an Infrastructure as a Service (IaaS) network, a Platform as a Service (PaaS) network, a Software as a Service (SaaS) network, other Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

The AV 102 can navigate roadways without a human driver based on sensor signals generated by multiple sensor systems 104, 106, and 108. The sensor systems 104-108 can include different types of sensors and can be arranged about the AV 102. For instance, the sensor systems 104-108 can comprise Inertial Measurement Units (IMUs), cameras (e.g., still image cameras, video cameras, etc.), light sensors (e.g., LIDAR systems, ambient light sensors, infrared sensors, etc.), RADAR systems, GPS receivers, audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 104 can be a camera system, the sensor system 106 can be a LIDAR system, and the sensor system 108 can be a RADAR system. Other embodiments may include any other number and type of sensors.

The AV 102 can also include several mechanical systems that can be used to maneuver or operate the AV 102. For instance, the mechanical systems can include a vehicle propulsion system 130, a braking system 132, a steering system 134, a safety system 136, and a cabin system 138, among other systems. The vehicle propulsion system 130 can include an electric motor, an internal combustion engine, or both. The braking system 132 can include an engine brake, brake pads, actuators, and/or any other suitable componentry configured to assist in decelerating the AV 102. The steering system 134 can include suitable componentry configured to control the direction of movement of the AV 102 during navigation. The safety system 136 can include lights and signal indicators, a parking brake, airbags, and so forth. The cabin system 138 can include cabin temperature control systems, in-cabin entertainment systems, and so forth. In some embodiments, the AV 102 might not include human driver actuators (e.g., steering wheel, handbrake, foot brake pedal, foot accelerator pedal, turn signal lever, window wipers, etc.) for controlling the AV 102. Instead, the cabin system 138 can include one or more client interfaces (e.g., Graphical User Interfaces (GUIs), Voice User Interfaces (VUIs), etc.) for controlling certain aspects of the mechanical systems 130-138.

The AV 102 can additionally include a local computing device 110 that is in communication with the sensor systems 104-108, the mechanical systems 130-138, the data center 150, and the client computing device 170, among other systems. The local computing device 110 can include one or more processors and memory, including instructions that can be executed by the one or more processors. The instructions can make up one or more software stacks or components responsible for controlling the AV 102; communicating with the data center 150, the client computing device 170, and other systems; receiving inputs from riders, passengers, and other entities within the AV’s environment; logging metrics collected by the sensor systems 104-108; and so forth. In this example, the local computing device 110 includes a perception stack 112, a mapping and localization stack 114, a prediction stack 116, a planning stack 118, a communications stack 120, a control stack 122, an AV operational database 124, and an HD geospatial database 126, among other stacks and systems.

The perception stack 112 can enable the AV 102 to “see” (e.g., via cameras, LIDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 104-108, the mapping and localization stack 114, the HD geospatial database 126, other components of the AV, and other data sources (e.g., the data center 150, the client computing device 170, third party data sources, etc.). The perception stack 112 can detect and classify objects and determine their current locations, speeds, directions, and the like. In addition, the perception stack 112 can determine the free space around the AV 102 (e.g., to maintain a safe distance from other objects, change lanes, park the AV, etc.). The perception stack 112 can also identify environmental uncertainties, such as where to look for moving objects, flag areas that may be obscured or blocked from view, and so forth. In some embodiments, an output of the prediction stack can be a bounding area around a perceived object that can be associated with a semantic label that identifies the type of object that is within the bounding area, the kinematic of the object (information about its movement), a tracked path of the object, and a description of the pose of the object (its orientation or heading, etc.).

The mapping and localization stack 114 can determine the AV’s position and orientation (pose) using different methods from multiple systems (e.g., GPS, IMUs, cameras, LIDAR, RADAR, ultrasonic sensors, the HD geospatial database 126, etc.). For example, in some embodiments, the AV 102 can compare sensor data captured in real-time by the sensor systems 104-108 to data in the HD geospatial database 126 to determine its precise (e.g., accurate to the order of a few centimeters or less) position and orientation. The AV 102 can focus its search based on sensor data from one or more first sensor systems (e.g., GPS) by matching sensor data from one or more second sensor systems (e.g., LIDAR). If the mapping and localization information from one system is unavailable, the AV 102 can use mapping and localization information from a redundant system and/or from remote data sources.

The prediction stack 116 can receive information from the localization stack 114 and objects identified by the perception stack 112 and predict a future path for the objects. In some embodiments, the prediction stack 116 can output several likely paths that an object is predicted to take along with a probability associated with each path. For each predicted path, the prediction stack 116 can also output a range of points along the path corresponding to a predicted location of the object along the path at future time intervals along with an expected error value for each of the points that indicates a probabilistic deviation from that point.

The planning stack 118 can determine how to maneuver or operate the AV 102 safely and efficiently in its environment. For example, the planning stack 118 can receive the location, speed, and direction of the AV 102, geospatial data, data regarding objects sharing the road with the AV 102 (e.g., pedestrians, bicycles, vehicles, ambulances, buses, cable cars, trains, traffic lights, lanes, road markings, etc.) or certain events occurring during a trip (e.g., emergency vehicle blaring a siren, intersections, occluded areas, street closures for construction or street repairs, double-parked cars, etc.), traffic rules and other safety standards or practices for the road, user input, and other relevant data for directing the AV 102 from one point to another and outputs from the perception stack 112, localization stack 114, and prediction stack 116. The planning stack 118 can determine multiple sets of one or more mechanical operations that the AV 102 can perform (e.g., go straight at a specified rate of acceleration, including maintaining the same speed or decelerating; turn on the left blinker, decelerate if the AV is above a threshold range for turning, and turn left; turn on the right blinker, accelerate if the AV is stopped or below the threshold range for turning, and turn right; decelerate until completely stopped and reverse; etc.), and select the best one to meet changing road conditions and events. If something unexpected happens, the planning stack 118 can select from multiple backup plans to carry out. For example, while preparing to change lanes to turn right at an intersection, another vehicle may aggressively cut into the destination lane, making the lane change unsafe. The planning stack 118 could have already determined an alternative plan for such an event. Upon its occurrence, it could help direct the AV 102 to go around the block instead of blocking a current lane while waiting for an opening to change lanes.

The control stack 122 can manage the operation of the vehicle propulsion system 130, the braking system 132, the steering system 134, the safety system 136, and the cabin system 138. The control stack 122 can receive sensor signals from the sensor systems 104-108 as well as communicate with other stacks or components of the local computing device 110 or a remote system (e.g., the data center 150) to effectuate operation of the AV 102. For example, the control stack 122 can implement the final path or actions from the multiple paths or actions provided by the planning stack 118. This can involve turning the routes and decisions from the planning stack 118 into commands for the actuators that control the AV’s steering, throttle, brake, and drive unit.

The communications stack 120 can transmit and receive signals between the various stacks and other components of the AV 102 and between the AV 102, the data center 150, the client computing device 170, and other remote systems. The communications stack 120 can enable the local computing device 110 to exchange information remotely over a network, such as through an antenna array or interface that can provide a metropolitan WIFI network connection, a mobile or cellular network connection (e.g., Third Generation (3G), Fourth Generation (4G), Long-Term Evolution (LTE), 5th Generation (5G), etc.), and/or other wireless network connection (e.g., License Assisted Access (LAA), Citizens Broadband Radio Service (CBRS), MULTEFIRE, etc.). The communications stack 120 can also facilitate the local exchange of information, such as through a wired connection (e.g., a user’s mobile computing device docked in an in-car docking station or connected via Universal Serial Bus (USB), etc.) or a local wireless connection (e.g., Wireless Local Area Network (WLAN), Bluetooth®, infrared, etc.).

The HD geospatial database 126 can store HD maps and related data of the streets upon which the AV 102 travels. In some embodiments, the HD maps and related data can comprise multiple layers, such as an areas layer, a lanes and boundaries layer, an intersections layer, a traffic controls layer, and so forth. The areas layer can include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer can include geospatial information of road lanes (e.g., lane centerline, lane boundaries, type of lane boundaries, etc.) and related attributes (e.g., direction of travel, speed limit, lane type, etc.). The lanes and boundaries layer can also include 3D attributes related to lanes (e.g., slope, elevation, curvature, etc.). The intersections layer can include geospatial information of intersections (e.g., crosswalks, stop lines, turning lane centerlines and/or boundaries, etc.) and related attributes (e.g., permissive, protected/permissive, or protected only left turn lanes; legal or illegal u-turn lanes; permissive or protected only right turn lanes; etc.). The traffic controls lane can include geospatial information of traffic signal lights, traffic signs, and other road objects and related attributes.

The AV operational database 124 can store raw AV data generated by the sensor systems 104-108, stacks 112 -122, and other components of the AV 102 and/or data received by the AV 102 from remote systems (e.g., the data center 150, the client computing device 170, etc.). In some embodiments, the raw AV data can include HD LIDAR point cloud data, image data, RADAR data, GPS data, and other sensor data that the data center 150 can use for creating or updating AV geospatial data or for creating simulations of situations encountered by AV 102 for future testing or training of various machine learning algorithms that are incorporated in the local computing device 110.

The data center 150 can be a private cloud (e.g., an enterprise network, a co-location provider network, etc.), a public cloud (e.g., an Infrastructure as a Service (IaaS) network, a Platform as a Service (PaaS) network, a Software as a Service (SaaS) network, or other Cloud Service Provider (CSP) network), a hybrid cloud, a multi-cloud, and so forth. The data center 150 can include one or more computing devices remote to the local computing device 110 for managing a fleet of AVs and AV-related services. For example, in addition to managing the AV 102, the data center 150 may also support a ridesharing service, a delivery service, a remote/roadside assistance service, street services (e.g., street mapping, street patrol, street cleaning, street metering, parking reservation, etc.), and the like.

The data center 150 can send and receive various signals to and from the AV 102 and the client computing device 170. These signals can include sensor data captured by the sensor systems 104-108, roadside assistance requests, software updates, ridesharing pick-up and drop-off instructions, and so forth. In this example, the data center 150 includes a data management platform 152, an Artificial Intelligence/Machine Learning (AI/ML) platform 154, a simulation platform 156, a remote assistance platform 158, and a ridesharing platform 160, among other systems.

The data management platform 152 can be a “big data” system capable of receiving and transmitting data at high velocities (e.g., near real-time or real-time), processing a large variety of data and storing large volumes of data (e.g., terabytes, petabytes, or more of data). The varieties of data can include data having different structured (e.g., structured, semi-structured, unstructured, etc.), data of different types (e.g., sensor data, mechanical system data, ridesharing service, map data, audio, video, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), or data having other heterogeneous characteristics. The various platforms and systems of the data center 150 can access data stored by the data management platform 152 to provide their respective services.

The AI/ML platform 154 can provide the infrastructure for training and evaluating machine learning algorithms for operating the AV 102, the simulation platform 156, the remote assistance platform 158, the ridesharing platform 160, and other platforms and systems. Using the AI/ML platform 154, data scientists can prepare data sets from the data management platform 152; select, design, and train machine learning models; evaluate, refine, and deploy the models; maintain, monitor, and retrain the models; and so on.

The simulation platform 156 can enable testing and validation of the algorithms, machine learning models, neural networks, and other development efforts for the AV 102, the remote assistance platform 158, the ridesharing platform 160, and other platforms and systems. The simulation platform 156 can replicate a variety of driving environments and/or reproduce real-world scenarios from data captured by the AV 102, including rendering geospatial information and road infrastructure (e.g., streets, lanes, crosswalks, traffic lights, stop signs, etc.) obtained from a cartography platform; modeling the behavior of other vehicles, bicycles, pedestrians, and other dynamic elements; simulating inclement weather conditions, different traffic scenarios; and so on.

The remote assistance platform 158 can generate and transmit instructions regarding the operation of the AV 102. For example, in response to an output of the AI/ML platform 154 or other system of the data center 150, the remote assistance platform 158 can prepare instructions for one or more stacks or other components of the AV 102.

The ridesharing platform 160 can interact with a customer of a ridesharing service via a ridesharing application 172 executing on the client computing device 170. The client computing device 170 can be any type of computing system, including a server, desktop computer, laptop, tablet, smartphone, smart wearable device (e.g., smartwatch, smart eyeglasses or other Head-Mounted Display (HMD), smart ear pods, or other smart in-ear, on-ear, or over-ear device, etc.), gaming system, or other general purpose computing device for accessing the ridesharing application 172. The client computing device 170 can be a customer’s mobile computing device or a computing device integrated with the AV 102 (e.g., the local computing device 110). The ridesharing platform 160 can receive requests to pick up or drop off from the ridesharing application 172 and dispatch the AV 102 for the trip.

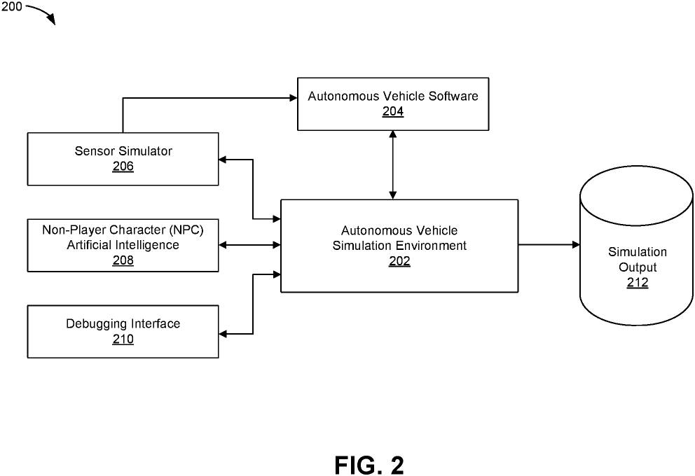

FIG. 2 illustrates an example system 200 for simulating the operation of an autonomous vehicle. In some aspects, system 200 can include autonomous vehicle (AV) simulation environment 202. In some cases, AV simulation environment 202 can be used to simulate and test the operation of AV software 204. For example, AV simulation environment 202 can be used to replicate scenarios that may be encountered by an AV (e.g., AV 102) in a real-world environment.

In some embodiments, AV simulation environment 202 can be configured to interface with sensor simulator 206. In some aspects, sensor simulator 206 can simulate one or more sensors associated with an AV such as sensor systems 104-108. In some examples, sensor simulator 206 can simulate the behavior of one or more sensors on an AV by capturing sensor data that is based on AV simulation environment 202. For instance, sensor simulator 206 can simulate a forward-facing camera on an AV by capturing image data from AV simulation environment 202 based on the position of the simulated AV (e.g., capture simulated traffic light status). In another example, sensor simulator 206 can simulate the operation of one or more LIDAR sensors by capturing LIDAR sensor data from AV simulation environment 202. In some cases, sensor simulator 206 can provide sensor data to AV software 204. In some examples, AV software 204 can use sensor data received from sensor simulator 206 to sense or perceive AV simulation environment 202.

In some aspects, AV simulation environment 202 can be configured to interface with non-player character (NPC) artificial intelligence (AI) 208. In some cases, NPC AI 208 can be used to control one or more NPCs within AV simulation environment 202. In some cases, NPC AI 208 can control the operation (e.g., position, movement, etc.) of pedestrians, vehicles, animals, and/or any other NPC within AV simulation environment 202.

In some cases, AV simulation environment 202 can be used to track the state or value of one or more simulation parameters associated with a simulated environment. In some cases, the one or more simulation parameters can include AV position, AV velocity, AV acceleration, AV sensor condition, AV door angle, AV wheel angle, AV headlight status, AV blinker status, AV hazard light status, AV windshield wiper status, timer status, NPC position, traffic light status, weather conditions, any other parameter associated with the AV or the simulated environment, and/or any combination thereof.

In some examples, the one or more simulation parameters associated with AV simulation environment 202 can change throughout a simulation time period. For instance, AV software 204 may cause the simulated AV to slow down based on sensor data (e.g., from sensor simulator 206) indicating that a pedestrian is crossing the street. In another example, AV software 204 may cause the simulated AV to accelerate based on sensor data indicating that a traffic light has changed from red to green.

In some aspects, AV simulation environment 202 can track changes in state or value of one or more simulation parameters. In some examples, AV simulation environment 202 can detect and store changes in the state or value of simulation parameters together with a corresponding timestamp. In some aspects, a simulation parameter may be associated with a finite number of states or a values (e.g., parameter may not be interpolated). For example, the status of a traffic light at any given time can have a value of red, green, or yellow. In another example, the AV headlights can correspond to a state of on, off, or high-beams. In some cases, AV simulation environment can store the state of the simulation parameter over time (e.g., using a function).

In some embodiments, AV simulation environment 202 may determine one or more functions that can be used to calculate the value of a simulation parameter at any given simulation time. In some aspects, the function may correspond to a spline (e.g., a piecewise polynomial) that can be used to interpolate the value of the simulation parameter. For example, AV simulation environment 202 may determine a function that can be used to interpolate the value of AV velocity at time t₁ based on the velocity at time t₀ and time t₂. In another example, AV simulation environment 202 may determine a function that can be used to calculate the value of AV acceleration at time t₁ based on the acceleration at time t₀ and time t₂.

In some cases, AV simulation environment may represent all of the simulation parameters using one or more functions that can be evaluated at any time within a simulation time period (e.g., irrespective of simulation tick time). In some embodiments, a function corresponding to a simulation parameter may be a linear function (e.g., function may assume linear pattern of change). In some aspects, a simulation parameter may be associated with multiple functions that correspond to different time periods within a simulation time period. For example, a first function may be used to calculate AV acceleration at simulation times between time t₀ and time t₁, and a second function may be used to calculate AV acceleration at simulation times between time t₁ and time t₂ (e.g., simulation time period from t₀ to t₂). In some cases, a simulation parameter may be associated with a single function that corresponds to the entire simulation time period (e.g., single function can return value at any simulation time from t₀ to t_{END}).

In some embodiments, AV simulation environment 202 may determine the function or functions associated with simulation parameters prior to running a simulation (e.g., simulation parameters unaffected by AV behavior). For example, a function associated with the path or position of an NPC (e.g., pedestrian walking on sidewalk) can be determined prior to simulation. In another example, a function associated with the status of a timer may also be determine prior to simulation. In some cases, AV simulation environment 202 may determine the function or functions associated with simulation parameters while the simulation is running. For instance, a function associated with the position of the AV can be determined as the AV moves during the simulation. In some cases, AV simulation environment 202 may determine the function or functions associated with simulation parameters after the simulation has completed.

In some aspects, AV simulation environment 202 may be configured to communicate with debugging interface 210. In some cases, debugging interface 210 can be used to query the value or state of one or more simulation parameters. For example, debugging interface 210 can be used to query the AV position at any time within the simulation time period. In some cases, debugging interface 210 can be used to query the value of all simulation parameters (e.g., a world state) within AV simulation environment 202 at a given time.

In some embodiments, debugging interface 210 can be used to evaluate simulation scenarios and determine required edits without re-running entire simulation. For instance, debugging interface 210 can be used to determine the value of a simulation parameter at any time without having to re-run the entire simulation. In some examples, an operator may determine that the position of a pedestrian at time t₁ is not within a desired range (e.g., for test scenario) of the simulated AV and may change the position without re-running the entire simulation.

In some aspects, debugging interface 210 can be used to determine simulation parameters to configure sensor simulator 206. For example, the intervals used to capture LIDAR data may not be synchronized with the interval steps (e.g., ticks) in AV simulation environment 202. For example, LIDAR sampling that is faster than interval steps in AV simulation environment 202 may result in subsequent LIDAR samples having same values for simulation parameters. In some aspects, debugging interface 210 can be used to query simulation parameters to determine the value of simulation parameters at time steps that occur within the interval steps of AV simulation environment 202 (e.g., based on simulation parameter functions). In some examples, the calculated values of the simulation parameters can be used to provide unique LIDAR samples that coincide with the LIDAR sampling rate.

In some examples, the functions associated with simulation parameters can be used to configure the timing of sensor simulator 206 (e.g., timing for capturing data from AV simulation environment 202). For example, capture of sensor data from AV simulation environment 202 can be reordered to minimize simulation time. In some cases, sensor simulator 206 can jump forward 0.1 s to capture camera data and then jump back 0.1 s to capture LIDAR data. In another example, a camera sensor capture can be reordered (e.g., delayed or moved up) to permit partial capture by a LIDAR sensor. In some aspects, the sensor data captured by sensor simulator 206 can be associated with timestamps that can be used to deliver sensor data to autonomous vehicle software 204 at a deterministic time (e.g., irrespective of the order or time it was captured from AV simulation environment 202).

In some examples, AV simulation environment 202 may store one or more simulation parameters, simulation parameter functions, timestamps, etc. in a database such as simulation output 212. In some cases, simulation output 212 can be used to query a world state (e.g., state of all simulation parameters) within AV simulation environment 202 at any time associated with a simulation.

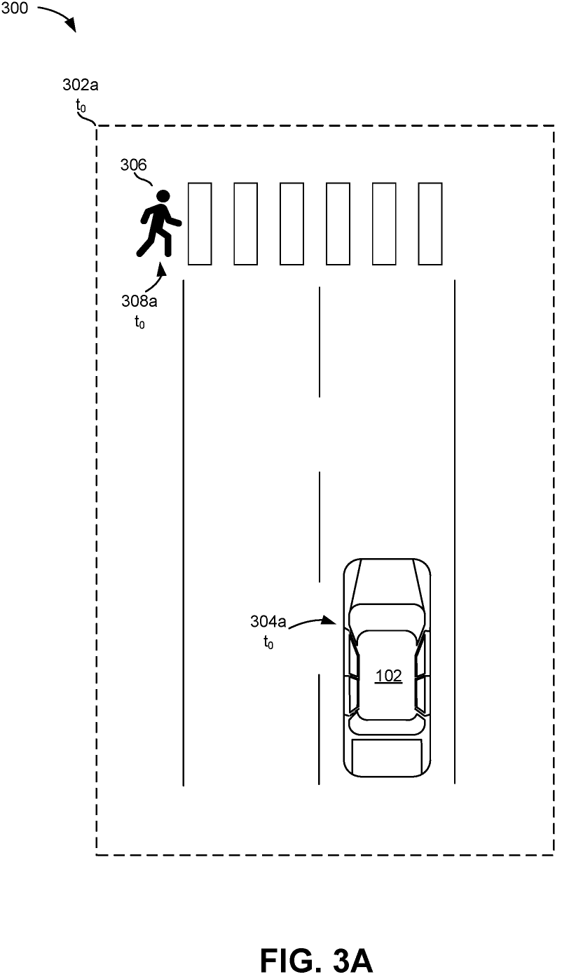

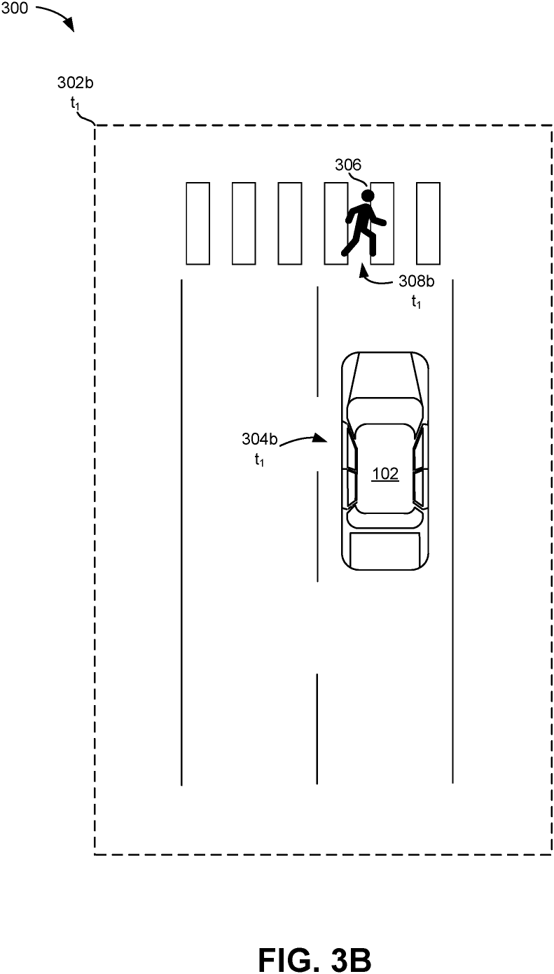

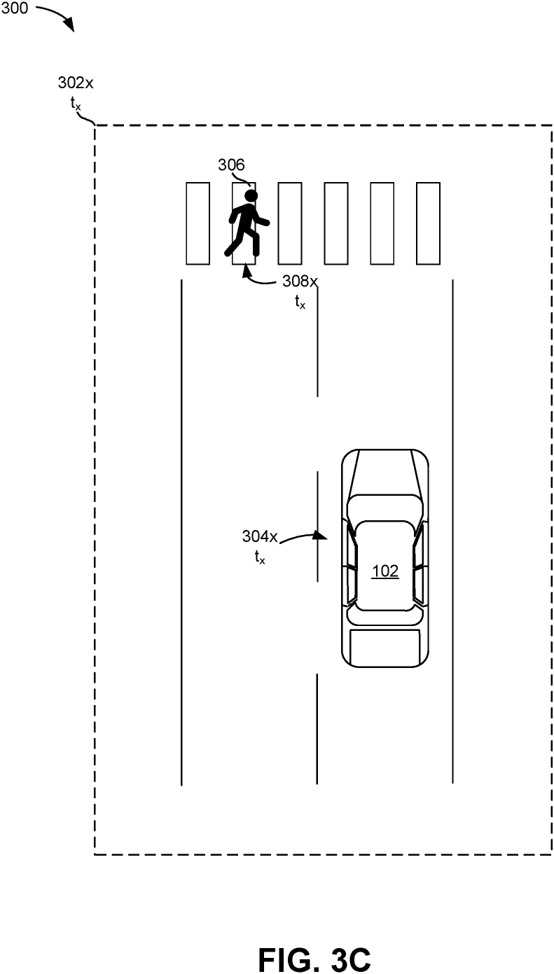

FIG. 3A illustrates an example of a simulation environment 300. In some aspects, simulation environment 300 can include a first world state 302a that is captured at time t₀. In some cases, time t₀ can correspond to a first time instance in a simulation sequence. In some embodiments, simulation environment 300 can be associated with one or more simulation parameters that can be determined at different times within a simulation time period (e.g., first world state 302a at time t₀). For example, simulation environment 300 can include a simulated AV 102 that is located at position 304a at time t₀. In another example, simulation environment 300 can include pedestrian 306 that is located at position 308a at time t₀.

FIG. 3B illustrates a second example of simulation environment 300. In some aspects, simulation environment 300 can include a second world state 302b that is captured at time t₁. In some cases, time t₁ can correspond to a second time instance in a simulation sequence. In some embodiments, simulation environment 300 can be associated with one or more simulation parameters that can be determined at different times within a simulation time period (e.g., second world state 302b at time t₁). For example, simulation environment 300 can include a simulated AV 102 that is located at position 304b at time t₁. In another example, simulation environment 300 can include pedestrian 306 that is located at position 308b at time t₁.

In some aspects, simulation environment 300 can determine one or more functions for calculating one or more simulation parameters. In some cases, the function can be based on data associated with world state 302a and world state 302b. For example, simulation environment 300 can use the positions of AV 102 at time t₀ (e.g., position 304a) and time t₁ (e.g., position 304b) to determine a continuous function that can be evaluated over time to determine the position of AV 102 at any time tₓ between t₀ and t₁. In some aspects, functions associated with simulation parameters that are based on AV performance can be determined in real-time and/or after the simulation is completed.

In another example, simulation environment 300 can use the positions of pedestrian 306 at time t₀ (e.g., position 308a) and time t₁ (e.g., position 308b) to determine a continuous function that can be evaluated over time to determine the position of AV 102 at any time tₓ between t₀ and t₁. In some cases, functions associated with simulation parameters that are independent of the AV performance (e.g., NPC position) can be determine prior to executing the simulation.

FIG. 3C illustrates a third example of simulation environment 300. In some aspects, simulation environment 300 can include a third world state 302x that is captured at time tₓ. In some aspects, time tₓ can correspond to a time that is between time t₀ (illustrated in FIG. 3A) and time t₁ (illustrated in FIG. 3B). In some cases, simulation environment 300 can use one or more functions associated with simulation parameters to return world state 302x. For example, simulation environment 300 can use a function for calculating the position of AV 102 to determine that AV 102 is located at position 304x at time tₓ. In another example, simulation environment 300 can use a function for calculating the position of pedestrian 306 to determine that pedestrian 306 is located at position 308x at time tₓ.

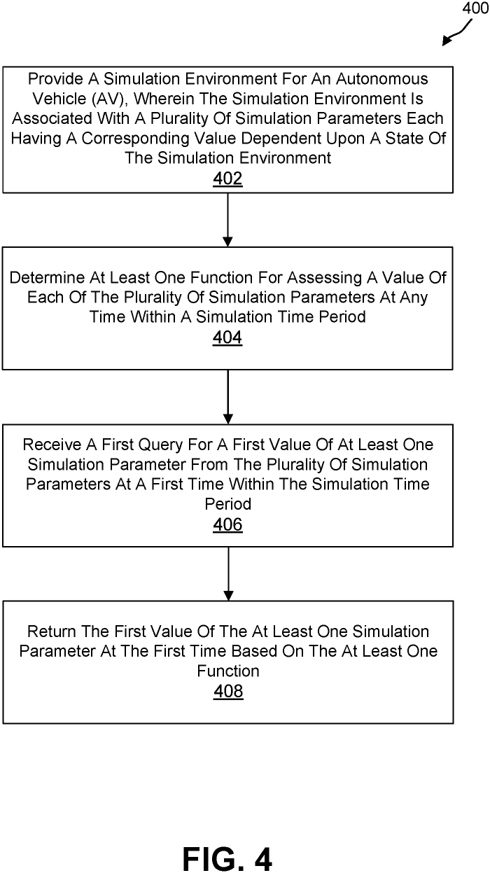

FIG. 4 illustrates a block diagram of an example process 400 for managing state information in a simulation environment. At block 402, the process 400 includes providing a simulation environment for an autonomous vehicle (AV), wherein the simulation environment is associated with a plurality of simulation parameters each having a corresponding value dependent upon a state of the simulation environment. For example, autonomous vehicle simulation environment 202 can be associated with a plurality of simulation parameters each having a corresponding value dependent upon a state of the simulation environment. As illustrated in FIG. 3A, AV 102 can have a position 304a that is associated with first world state 302a (e.g., world state at time t₀). In some cases, the plurality of simulation parameters can include at least one of an AV position, an AV velocity, an AV acceleration, an AV sensor fault, an AV door angle, an AV light, a timer, and a non-player character (NPC) position.

At block 404, the process 400 includes determining at least one function for assessing a value of each of the plurality of simulation parameters at any time within a simulation time period. For example, AV simulation environment 202 can determine at least one function for assessing a value of each of the plurality of simulation parameters at any time within a simulation time period. In some cases, the at least one function can correspond to at least one spline.

At block 406, the process 400 includes receiving a first query for a first value of at least one simulation parameter from the plurality of simulation parameters at a first time within the simulation time period. For instance, debugging interface 210 can be used to query AV simulation environment 202 for a first value of at least one simulation parameter. In some cases, the first query can be received from a sensor simulator configured to provide sensor data to the AV, wherein the sensor data is based on the first value. For example, sensor simulator 206 can query AV simulated environment 202 for the first value and use the first value to create sensor data that is provided to AV software 204.

At block 408, the process 400 includes returning the first value of the at least one simulation parameter at the first time based on the at least one function. For example, AV simulation environment 202 can return the first value of the at least one simulation parameter to debugging interface 210.

In some aspects, the process 400 can include receiving a second query for a second value of the at least one simulation parameter at a second time within the simulation time period, wherein the second time occurs before the first time and returning the second value of the at least one simulation parameter at the second time based on the at least one function. For instance, debugging interface 210 can be used to query AV simulation environment 202 for a second value of the at least one simulation parameter at a second time that occurs before the first time. In some cases, AV simulation environment 202 can return the second value to the debugging interface 210 (e.g., without re-running the simulation).

In some embodiments, the process 400 can include receiving simulation data corresponding to at least one non-player character (NPC) in the simulation environment at a first data rate and receiving simulation data from the AV at a second data rate, wherein the first data rate is different from the second data rate. For example, AV simulation environment 202 can receive simulation data from NPC AI 208 at a first data rate and also receive simulation data from AV software 204 at second data rate that is different from the first data rate. In some cases, AV simulation environment 202 can use functions associated with simulation parameters to align data points that are received at different data rates (e.g., different tick times).

In some examples, the process 400 may include receiving an input to modify at least one element in the simulation environment that is associated with the at least one parameter. For example, AV simulation environment 202 can receive an input from NPC AI 208 to modify a position of a pedestrian (e.g., the at least one parameter).

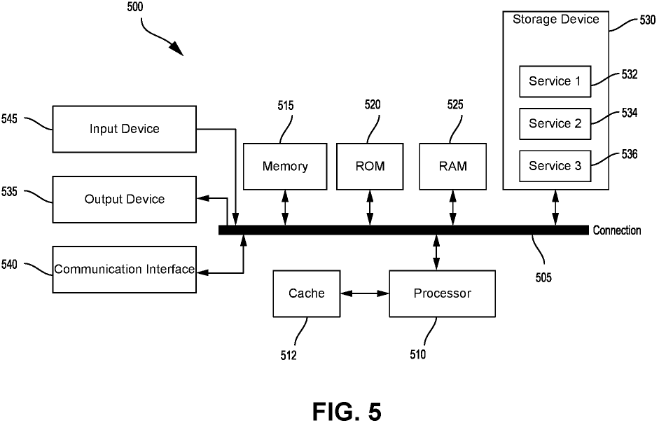

FIG. 5 illustrates an example processor-based system with which some aspects of the subject technology can be implemented. For example, processor-based system 500 can be any computing device making up internal computing device 110, data center 150, client computing device 170, autonomous vehicle simulation environment 202, or any component thereof in which the components of the system are in communication with each other using connection 505. Connection 505 can be a physical connection via a bus, or a direct connection into processor 510, such as in a chipset architecture. Connection 505 can also be a virtual connection, networked connection, or logical connection.

In some embodiments, computing system 500 is a distributed system in which the functions described in this disclosure can be distributed within a datacenter, multiple data centers, a peer network, etc. In some embodiments, one or more of the described system components represents many such components each performing some or all of the function for which the component is described. In some embodiments, the components can be physical or virtual devices.

Example system 500 includes at least one processing unit (CPU or processor) 510 and connection 505 that couples various system components including system memory 515, such as read-only memory (ROM) 520 and random access memory (RAM) 525 to processor 510. Computing system 500 can include a cache of high-speed memory 512 connected directly with, in close proximity to, or integrated as part of processor 510.

Processor 510 can include any general purpose processor and a hardware service or software service, such as services 532, 534, and 536 stored in storage device 530, configured to control processor 510 as well as a special-purpose processor where software instructions are incorporated into the actual processor design. Processor 510 may essentially be a completely self-contained computing system, containing multiple cores or processors, a bus, memory controller, cache, etc. A multi-core processor may be symmetric or asymmetric.

To enable user interaction, computing system 500 includes an input device 545, which can represent any number of input mechanisms, such as a microphone for speech, a touch-sensitive screen for gesture or graphical input, keyboard, mouse, motion input, speech, etc. Computing system 500 can also include output device 535, which can be one or more of a number of output mechanisms known to those of skill in the art. In some instances, multimodal systems can enable a user to provide multiple types of input/output to communicate with computing system 500. Computing system 500 can include communications interface 540, which can generally govern and manage the user input and system output. The communication interface may perform or facilitate receipt and/or transmission wired or wireless communications via wired and/or wireless transceivers, including those making use of an audio jack/plug, a microphone jack/plug, a universal serial bus (USB) port/plug, an Apple® Lightning® port/plug, an Ethernet port/plug, a fiber optic port/plug, a proprietary wired port/plug, a BLUETOOTH® wireless signal transfer, a BLUETOOTH® low energy (BLE) wireless signal transfer, an IBEACON® wireless signal transfer, a radio-frequency identification (RFID) wireless signal transfer, near-field communications (NFC) wireless signal transfer, dedicated short range communication (DSRC) wireless signal transfer, 802.11 Wi-Fi wireless signal transfer, wireless local area network (WLAN) signal transfer, Visible Light Communication (VLC), Worldwide Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/5G/LTE cellular data network wireless signal transfer, ad-hoc network signal transfer, radio wave signal transfer, microwave signal transfer, infrared signal transfer, visible light signal transfer, ultraviolet light signal transfer, wireless signal transfer along the electromagnetic spectrum, or some combination thereof.

Communication interface 540 may also include one or more Global Navigation Satellite System (GNSS) receivers or transceivers that are used to determine a location of the computing system 500 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 530 can be a non-volatile and/or non-transitory and/or computer-readable memory device and can be a hard disk or other types of computer readable media which can store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a compact disc read only memory (CD-ROM) optical disc, a rewritable compact disc (CD) optical disc, digital video disk (DVD) optical disc, a blu-ray disc (BDD) optical disc, a holographic optical disk, another optical medium, a secure digital (SD) card, a micro secure digital (microSD) card, a Memory Stick® card, a smartcard chip, a EMV chip, a subscriber identity module (SIM) card, a mini/micro/nano/pico SIM card, another integrated circuit (IC) chip/card, random access memory (RAM), static RAM (SRAM), dynamic RAM (DRAM), read-only memory (ROM), programmable read-only memory (PROM), erasable programmable read-only memory (EPROM), electrically erasable programmable read-only memory (EEPROM), flash EPROM (FLASHEPROM), cache memory (L1/L2/L3/L4/L5/L#), resistive random-access memory (RRAM/ReRAM), phase change memory (PCM), spin transfer torque RAM (STT-RAM), another memory chip or cartridge, and/or a combination thereof.

Storage device 530 can include software services, servers, services, etc., that when the code that defines such software is executed by the processor 510, it causes the system to perform a function. In some embodiments, a hardware service that performs a particular function can include the software component stored in a computer-readable medium in connection with the necessary hardware components, such as processor 510, connection 505, output device 535, etc., to carry out the function.

As understood by those of skill in the art, machine-learning based classification techniques can vary depending on the desired implementation. For example, machine-learning classification schemes can utilize one or more of the following, alone or in combination: hidden Markov models; recurrent neural networks; convolutional neural networks (CNNs); deep learning; Bayesian symbolic methods; general adversarial networks (GANs); support vector machines; image registration methods; applicable rule-based system. Where regression algorithms are used, they may include including but are not limited to: a Stochastic Gradient Descent Regressor, and/or a Passive Aggressive Regressor, etc.

Machine learning classification models can also be based on clustering algorithms (e.g., a Mini-batch K-means clustering algorithm), a recommendation algorithm (e.g., a Mini wise Hashing algorithm, or Euclidean Locality-Sensitive Hashing (LSH) algorithm), and/or an anomaly detection algorithm, such as a Local outlier factor. Additionally, machine-learning models can employ a dimensionality reduction approach, such as, one or more of: a Mini-batch Dictionary Learning algorithm, an Incremental Principal Component Analysis (PCA) algorithm, a Latent Dirichlet Allocation algorithm, and/or a Mini-batch K-means algorithm, etc.

Embodiments within the scope of the present disclosure may also include tangible and/or non-transitory computer-readable storage media or devices for carrying or having computer-executable instructions or data structures stored thereon. Such tangible computer-readable storage devices can be any available device that can be accessed by a general purpose or special purpose computer, including the functional design of any special purpose processor as described above. By way of example, and not limitation, such tangible computer-readable devices can include RAM, ROM, EEPROM, CD-ROM or other optical disk storage, magnetic disk storage or other magnetic storage devices, or any other device which can be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special purpose computer, or special purpose processing device to perform a certain function or group of functions. Computer-executable instructions also include program modules that are executed by computers in stand-alone or network environments. Generally, program modules include routines, programs, components, data structures, objects, and the functions inherent in the design of special-purpose processors, etc. that perform tasks or implement abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Other embodiments of the disclosure may be practiced in network computing environments with many types of computer system configurations, including personal computers, hand-held devices, multi-processor systems, microprocessor-based or programmable consumer electronics, network PCs, minicomputers, mainframe computers, and the like. Embodiments may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

The various embodiments described above are provided by way of illustration only and should not be construed to limit the scope of the disclosure. For example, the principles herein apply equally to optimization as well as general improvements. Various modifications and changes may be made to the principles described herein without following the example embodiments and applications illustrated and described herein, and without departing from the spirit and scope of the disclosure. Claim language reciting “at least one of” a set indicates that one member of the set or multiple members of the set satisfy the claim. For example, claim language reciting “at least one of A and B” means A, B, or A and B.

What is claimed is:

1. A system comprising:
one or more processors; and
a computer-readable storage medium coupled to the one or more processors, wherein the computer-readable storage medium comprises instructions that are configured to cause the one or more processors to perform operations comprising:
providing a simulation environment for an autonomous vehicle (AV), wherein the simulation environment is associated with a plurality of simulation parameters each having a corresponding value dependent upon a state of the simulation environment;
determining at least one function for assessing a value of each of the plurality of simulation parameters at any time within a simulation time period;
receiving a first query for a first value of at least one simulation parameter from the plurality of simulation parameters at a first time within the simulation time period; and
returning the first value of the at least one simulation parameter at the first time based on the at least one function.

2. The system of claim 1, the computer-readable storage medium storing instructions which, when executed by the one or more processors, cause the one or more processors to:
receiving a second query for a second value of the at least one simulation parameter at a second time within the simulation time period, wherein the second time occurs before the first time; and
returning the second value of the at least one simulation parameter at the second time based on the at least one function.

3. The system of claim 1, wherein the at least one function corresponds to at least one spline.

4. The system of claim 1, wherein the first query is received from a sensor simulator configured to provide sensor data to the AV, wherein the sensor data is based on the first value.

5. The system of claim 1, wherein the plurality of simulation parameters includes at least one of an AV position, an AV velocity, an AV acceleration, an AV sensor fault, an AV door angle, an AV light, a timer, and a non-player character (NPC) position.

6. The system of claim 1, the computer-readable storage medium storing instructions which, when executed by the one or more processors, cause the one or more processors to:
receiving simulation data corresponding to at least one non-player character (NPC) in the simulation environment at a first data rate; and
receiving simulation data from the AV at a second data rate, wherein the first data rate is different from the second data rate.

7. The system of claim 1, the computer-readable storage medium storing instructions which, when executed by the one or more processors, cause the one or more processors to:
receiving an input to modify at least one element in the simulation environment that is associated with the at least one simulation parameter.

8. A method, comprising:
providing a simulation environment for an autonomous vehicle (AV), wherein the simulation environment is associated with a plurality of simulation parameters each having a corresponding value dependent upon a state of the simulation environment;
determining at least one function for assessing a value of each of the plurality of simulation parameters at any time within a simulation time period;
receiving a first query for a first value of at least one simulation parameter from the plurality of simulation parameters at a first time within the simulation time period; and
returning the first value of the at least one simulation parameter at the first time based on the at least one function.

9. The method of claim 8, further comprising:
receiving a second query for a second value of the at least one simulation parameter at a second time within the simulation time period, wherein the second time occurs before the first time; and
returning the second value of the at least one simulation parameter at the second time based on the at least one function.

10. The method of claim 8, wherein the at least one function corresponds to at least one spline.

11. The method of claim 8, wherein the first query is received from a sensor simulator configured to provide sensor data to the AV, wherein the sensor data is based on the first value.

12. The method of claim 8, wherein the plurality of simulation parameters includes at least one of an AV position, an AV velocity, an AV acceleration, an AV sensor fault, an AV door angle, an AV light, a timer, and a non-player character (NPC) position.

13. The method of claim 8, further comprising:
receiving simulation data corresponding to at least one non-player character (NPC) in the simulation environment at a first data rate; and
receiving simulation data from the AV at a second data rate, wherein the first data rate is different from the second data rate.

14. The method of claim 8, further comprising:
receiving an input to modify at least one element in the simulation environment that is associated with the at least one simulation parameter.

15. A non-transitory computer-readable storage medium comprising instructions stored therein, which when executed by one or more processors, cause the one or more processors to perform operations comprising:
provide a simulation environment for an autonomous vehicle (AV), wherein the simulation environment is associated with a plurality of simulation parameters each having a corresponding value dependent upon a state of the simulation environment;
determine at least one function for assessing a value of each of the plurality of simulation parameters at any time within a simulation time period;
receive a first query for a first value of at least one simulation parameter from the plurality of simulation parameters at a first time within the simulation time period; and
return the first value of the at least one simulation parameter at the first time based on the at least one function.

16. The non-transitory computer-readable storage medium of claim 15, comprising instructions which, when executed by the one or more processors, cause the one or more processors to perform operations comprising:
receive a second query for a second value of the at least one simulation parameter at a second time within the simulation time period, wherein the second time occurs before the first time; and
return the second value of the at least one simulation parameter at the second time based on the at least one function.

17. The non-transitory computer-readable storage medium of claim 15, wherein the at least one function corresponds to at least one spline.

18. The non-transitory computer-readable storage medium of claim 15, wherein the first query is received from a sensor simulator configured to provide sensor data to the AV, wherein the sensor data is based on the first value.

19. The non-transitory computer-readable storage medium of claim 15, comprising instructions which, when executed by the one or more processors, cause the one or more processors to perform operations comprising:
receive simulation data corresponding to at least one non-player character (NPC) in the simulation environment at a first data rate; and
receive simulation data from the AV at a second data rate, wherein the first data rate is different from the second data rate.

20. The non-transitory computer-readable storage medium of claim 15, comprising instructions which, when executed by the one or more processors, cause the one or more processors to perform operations comprising:
receive an input to modify at least one element in the simulation environment that is associated with the at least one simulation parameter.
